(19) United States
(12) Patent Application Publication
(10) Pub. No.: US 2026/0107660 A1
(43) Pub. Date: Apr. 16, 2026

(54) DISPLAY DEVICE AND METHOD OF MANUFACTURING THE SAME

(71) Applicant: Samsung Display Co., LTD., Yongin-si (KR)

(72) Inventors: Jung Ho CHOI, Yongin-si (KR); Young Kuk KIM, Yongin-si (KR); Tae Sun PARK, Yongin-si (KR); Seok Hwan BANG, Yongin-si (KR); Jeong Hyuck JANG, Yongin-si (KR)

(73) Assignee: Samsung Display Co., LTD., Yongin-si (KR)

(21) Appl. No.: 19/230,322

(22) Filed: Jun. 6, 2025

(30) Foreign Application Priority Data
Oct. 10, 2024 (KR) 10-2024-0137252

(51) Int. Cl. H10K 59/80; H10K 59/12; H10K 59/122

(52) U.S. Cl. CPC H10K 59/80517; H10K 59/1201; H10K 59/122

(57) ABSTRACT

A display device includes: a substrate; a first electrode disposed on the substrate; a pixel defining layer including an opening which exposes at least a portion of the first electrode; a light emitting layer disposed on the first electrode in the opening; and a second electrode disposed on the light emitting layer and the pixel defining layer, wherein the first electrode includes a first conductive layer including silver (Ag), palladium (Pd) and copper (Cu), and in the first conductive layer, content of the silver (Ag) is about 97 wt % to about 99 wt %, content of the palladium (Pd) is about 0.1 wt % to about 2.9 wt %, and content of the copper (Cu) is about 0.1 wt % to about 2.9 wt %.

### CROSS-REFERENCE TO RELATED APPLICATION(S)

This application claims to and benefits of Korean Patent Application No. 10-2024-0137252, filed on Oct. 10, 2024 under 35 U.S.C. § 119, in the Korean Intellectual Property Office, the entire contents of which are incorporated herein by reference.

### BACKGROUND

### 1. Technical Field

The disclosure relates to a display device and a method of manufacturing the display device.

### 2. Description of the Related Art

As the information society develops, demands for display devices for displaying images are increasing in various forms. The display devices may be flat panel display devices such as liquid crystal display devices, field emission display devices, and light emitting display devices. The light emitting display devices may include an organic light emitting display device including an organic light emitting element, an inorganic light emitting display device including an inorganic light emitting element such as an inorganic semiconductor, and a micro-light emitting display device or a nano-light emitting display device including a micro-light emitting element or a nano-light emitting element.

### SUMMARY

Aspects of the disclosure provide a display device capable of preventing or minimizing a reduction in the reflectance of a display panel by increasing the silver content of an APC alloy while preventing the creation of voids in a light emitting layer that emits light.

However, embodiments are not limited to those set forth herein. The above and other embodiments will become more apparent to one of ordinary skill in the art to which the disclosure pertains by referencing the detailed description of the disclosure given below.

According to an aspect of the disclosure, a display device includes: a substrate; a first electrode may be disposed on the substrate; a pixel defining layer comprising an opening which exposes at least a portion of the first electrode; a light emitting layer may be disposed on the first electrode in the opening; and a second electrode may be disposed on the light emitting layer and the pixel defining layer, wherein the first electrode may comprise a first conductive layer comprising silver (Ag), palladium (Pd) and copper (Cu), and in the first conductive layer, content of the silver (Ag) is in a range of about 97 wt % to about 99 wt %, content of the palladium (Pd) is a range of about 0.1 wt % to about 2.9 wt %, and content of the copper (Cu) is a range of about 0.1 wt % to about 2.9 wt %.

The first electrode further comprises: a second conductive layer disposed under the first conductive layer and including a conductive oxide; and a third conductive layer disposed on the first conductive layer and comprising a conductive oxide.

The conductive oxide may include at least one of indium-tin oxide (ITO), zinc oxide (ZnO), zinc-tin oxide (ZTO), indium-zinc oxide (IZO), indium-gallium oxide (IGO), indium-gallium-zinc oxide (IGZO), indium-gallium-tin oxide (IGTO), indium-tin-zinc oxide (ITZO), aluminum-doped zinc oxide (AZO), gallium-doped zinc oxide (GZO), gallium-tin oxide (GTO), and fluorine-doped tin oxide (FTO).

The pixel defining layer may include at least one halogen element among Cl, Br, and I.

Content of the at least one halogen element in the pixel defining layer may be in a range of about 1 wt % to about 30 wt %.

The pixel defining layer may include a light blocking material.

The display device may further include a transistor which comprises a semiconductor layer disposed between the substrate and the first electrode and electrically connected to the first electrode, wherein the semiconductor layer may include an oxide semiconductor comprising at least one of indium (In), gallium (Ga), zinc (Zn), tin (Sn), and hafnium (Hf).

The semiconductor layer may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO).

According to another aspect of the disclosure, a method of manufacturing a display device includes: forming a transistor, which includes a semiconductor layer, on a substrate; forming a first electrode on the transistor; forming a pixel defining layer which includes an opening exposing at least a portion of the first electrode; forming a light emitting layer on the first electrode in the opening; and forming a second electrode on the light emitting layer and the pixel defining layer, wherein the forming of the first electrode may include forming a first conductive layer under an oxygen (O₂) concentration of about 3% or less, and the first conductive layer comprises silver (Ag), palladium (Pd) and copper (Cu).

The first conductive layer may include about 97 wt % to about 99 wt % of silver (Ag), about 0.1 wt % to about 2.9 wt % of palladium (Pd), and about 0.1 wt % to about 2.9 wt % of copper (Cu).

The forming of the first electrode may include forming a second conductive layer may include a conductive oxide before the forming of the first conductive layer and forming a third conductive layer may include the conductive oxide on the first conductive layer, and the first conductive layer may be disposed on the second conductive layer.

The conductive oxide may include at least one of indium-tin oxide (ITO), zinc oxide (ZnO), zinc-tin oxide (ZTO), indium-zinc oxide (IZO), indium-gallium oxide (IGO), indium-gallium-zinc oxide (IGZO), indium-gallium-tin oxide (IGTO), indium-tin-zinc oxide (ITZO), aluminum-doped zinc oxide (AZO), gallium-doped zinc oxide (GZO), gallium-tin oxide (GTO), and fluorine-doped tin oxide (FTO).

The pixel defining layer may include at least one halogen element among Cl, Br, and I.

Content of the at least one halogen element in the pixel defining layer may be in a range of about 1 wt % to about 30 wt %.

The pixel defining layer may include a light blocking material.

The semiconductor layer may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO).

According to another aspect of the disclosure, an electronic device includes: a display device that provides an image; and a processor that transmits an image data signal to the display device, and the display device, wherein the display device comprising: a substrate; a first electrode disposed on the substrate; a pixel defining layer comprising an opening which exposes at least a portion of the first electrode; a light emitting layer disposed on the first electrode in the opening; and a second electrode disposed on the light emitting layer and the pixel defining layer, wherein the first electrode comprises a first conductive layer comprising silver (Ag), palladium (Pd) and copper (Cu), and in the first conductive layer, content of the silver (Ag) is in a range of about 97 wt % to about 99 wt %, content of the palladium (Pd) is in a range of about 0.1 wt % to about 2.9 wt %, and content of the copper (Cu) is in a range of about 0.1 wt % to about 2.9 wt %.

According to the display device according to the embodiments, by applying a conductive layer having a controlled content ratio of silver, palladium, and copper to the electrode, the ionization phenomenon of silver (Ag) is improved, and the reaction with the halogen element included in the pixel defining layer (PDL) is suppressed, so that the generation of salt due to the reaction with silver (Ag) may be prevented, and defects such as voids and dark spots may be suppressed.

The effects according to the embodiments are not limited to the contents exemplified above, and more diverse effects are included in the specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic perspective view of a display device according to an embodiment;

FIG. 2 is a schematic layout view of a display panel according to an embodiment;

FIG. 3A is a schematic cross-sectional view of the display panel according to the embodiment;

FIG. 3B is an enlarged schematic cross-sectional view of area A of the display panel according to the embodiment;

FIG. 3C is an enlarged schematic cross-sectional view of area B of the display panel according to the embodiment;

FIGS. 4A and 4B are respectively scanning electron microscope (SEM) images of surfaces of Example 1 and Comparative Example 1 measured after heat treatment at a temperature of 450° C. for one hour;

FIG. 5 is a schematic graph illustrating the transmittance of display panels of Example 1 and Comparative Example 1 with respect to wavelength region;

FIG. 6 is a schematic graph illustrating the reflectance of the display panels of Example 1 and Comparative Example 1 with respect to wavelength region;

FIG. 7 is a schematic graph illustrating the absorbance of the display panels of Example 1 and Comparative Example 1 with respect to wavelength region;

FIG. 8 is a surface image of the display panel manufactured according to Example 1.

FIG. 9 is a surface image of the display panel manufactured according to Comparative Example 1.

FIG. 10 is a surface image of a display panel manufactured according to Comparative Example 2.

FIG. 11 is a surface image of a display panel manufactured according to Comparative Example 3;

FIG. 12 is a schematic graph illustrating the transmittance of the display panels of Example 1 and Comparative Examples 2 and 3 with respect to wavelength region;

FIG. 13 is a schematic graph illustrating the reflectance of the display panels of Example 1 and Comparative Examples 2 and 3 with respect to wavelength region;

FIG. 14 is a schematic graph illustrating the absorbance of the display panels of Example 1 and Comparative Examples 2 and 3 with respect to wavelength region;

FIG. 15 is a schematic graph illustrating the transmittance of display panels of Examples 1 and 2 and Comparative Examples 1, 4 and 5 with respect to wavelength region;

FIG. 16 is a schematic graph illustrating the reflectance of the display panels of Examples 1 and 2 and Comparative Examples 1, 4 and 5 with respect to wavelength region;

FIG. 17 is a schematic graph illustrating the sheet resistance of the display panels of Examples 1 and 2 and Comparative Examples 1, 4 and 5 over time;

FIG. 18 is a schematic perspective view of an electronic device to which a display device according to an embodiment is applied;

FIG. 19 is a block diagram of an electronic device according to an embodiment; and

FIG. 20 is a schematic diagram of electronic devices according to various embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z—axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within +20%, +10%, or +5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

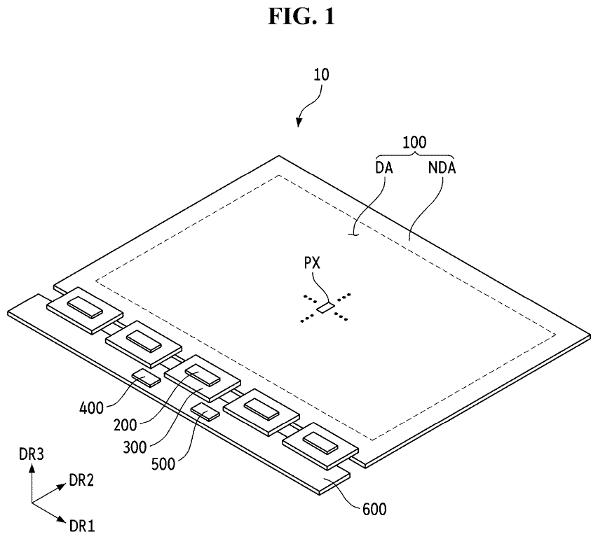

FIG. 1 is a schematic perspective view of a display device 10 according to an embodiment.

Referring to FIG. 1, the display device 10 may be a device for displaying moving images or still images. The display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various products such as televisions, notebook computers, monitors, billboards, and Internet of things (IOT) devices.

The display device 10 may be a light emitting display device such as an organic light emitting display device using an organic light emitting diode, a quantum dot light emitting display device including a quantum dot light emitting layer, an inorganic light emitting display device including an inorganic semiconductor, or a micro-light emitting display device or a nano-light emitting display device using a micro-light emitting diode or a nano-light emitting diode. A case where the display device 10 is an organic light emitting display device will be described below, but embodiments are not limited thereto.

The display device 10 may include a display panel 100, multiple source driving circuits 200, multiple flexible circuit boards 300, a timing control circuit 400, a power supply circuit 500, and a circuit board 600.

The display panel 100 may be shaped like a rectangular plane having long sides in a first direction DR1 and short sides in a second direction DR2 intersecting the first direction DR1. Each corner where a long side extending in the first direction DR1 meets a short side extending in the second direction DR2 may be rounded to have a selected curvature or may be right-angled. The planar shape of the display panel 100 is not limited to a quadrilateral shape but may also be other polygonal shapes, a circular shape, or an elliptical shape. The display panel 100 may be flat, but embodiments are not limited thereto. For example, the display panel 100 may include a curved portion, which is formed at left and right ends and has a constant or varying curvature. For example, the display panel 100 may be formed to be flexible so that the display panel 100 may be curved, bent, folded, or rolled.

The display panel 100 may include a display area DA, which displays an image, and a non-display area NDA disposed around the display area DA. A substrate SUB of the display panel 100 may include the display area DA and the non-display area NDA.

The display area DA may occupy most of the area of the display panel 100. The display area DA may be disposed in the center portion of the display panel 100. Pixels PX may be disposed in the display area DA to display an image. The display area DA may be an area that displays an image by including the pixels PX. For example, the display area DA may include pixel areas where the pixels PX are disposed.

The non-display area NDA may be an area that does not display an image. The non-display area NDA may be an edge area of the display panel 100. The non-display area NDA may be an area outside the display area DA. The non-display area NDA may surround the display area DA.

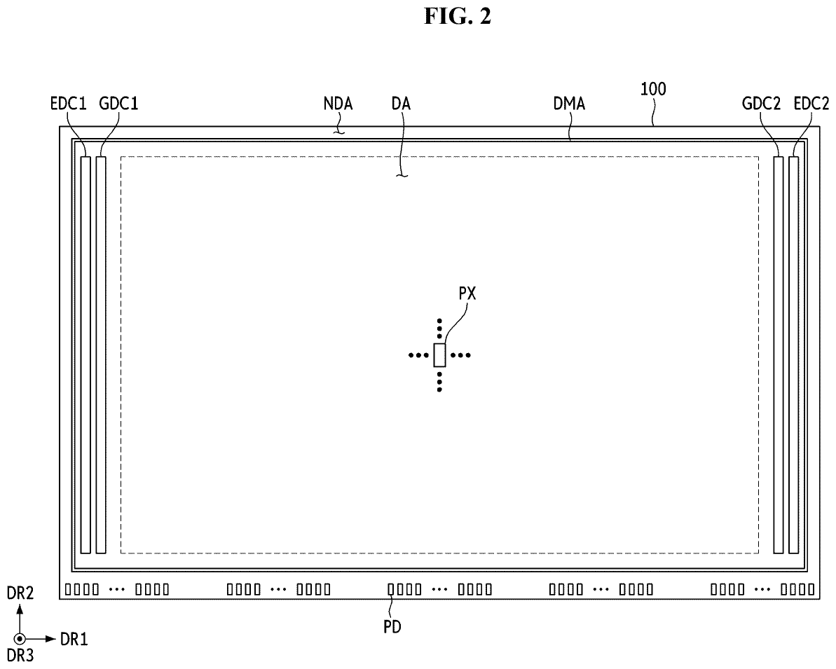

Display pads PD (see FIG. 2) may be disposed in the non-display area NDA so as to be connected to the flexible circuit boards 300. The display pads PD (see FIG. 2) may be disposed at an edge portion of the display panel 100.

Each of the source driving circuits 200 may be formed as an integrated circuit and attached to a corresponding flexible circuit board 300, but embodiments are not limited thereto. Each of the source driving circuits 200 may be attached onto the display panel 100 using a chip on glass (COG) method, a chip on plastic (COP) method, or an ultrasonic bonding method.

Each of the flexible circuit boards 300 may be disposed on the display pads PD (see FIG. 2) disposed at the edge portion of the display panel 100. Each of the flexible circuit boards 300 may be attached to the display pads PD (see FIG. 2) using a conductive adhesive member such as an anisotropic conductive film. Accordingly, the flexible circuit boards 300 may be electrically connected to signal lines of the display panel 100. Each of the flexible circuit boards 300 may be a flexible printed circuit board or a flexible film such as a chip on film.

The timing control circuit 400 may generate timing control signals that control the timing of scan driving circuits GDC1 and GDC2 (see FIG. 2), emission driving circuits EDC1 and EDC2 (see FIG. 2), and the source driving circuits 200. The power supply circuit 500 may generate power voltages that drive the display panel 100 according to power input from the outside. Each of the timing control circuit 400 and the power supply circuit 500 may be formed as an integrated circuit and attached to the circuit board 600.

The circuit board 600 may be connected to a side of each of the flexible circuit boards 300. The circuit board 600 may be a rigid printed circuit board.

FIG. 2 is a schematic layout view of a display panel 100 according to an embodiment.

Referring to FIG. 2, the display panel 100 may include display pads PD, a first scan driving circuit GDC1, a first emission driving circuit EDC1, a second scan driving circuit GDC2, a second emission driving circuit EDC2, and a dam area DMA.

The display pads PD may be disposed at an edge portion of the display panel 100. The display pads PD may be divided into multiple groups. In case that the display device 10 includes five flexible circuit boards 300 as in FIG. 1, the display pads PD may be divided into five groups. The display pads PD of each of the groups may have a one-to-one correspondence with bumps of a corresponding flexible circuit board 300. Therefore, the display pads PD of each of the groups may be electrically connected to the corresponding flexible circuit board 300.

Some of the display pads PD may be electrically connected to data lines disposed in the display area DA. Some others of the display pads PD may be electrically connected to the first scan driving circuit GDC1, the second scan driving circuit GDC2, the first emission driving circuit EDC1, and the second emission driving circuit EDC2. Some others of the display pads PD may be connected to power lines to which a first power voltage is applied.

The first scan driving circuit GDC1 and the second scan driving circuit GDC2 may be electrically connected to scan lines of the display area DA. The first scan driving circuit GDC1 may be disposed in the non-display area NDA on a first side (e.g., left side) of the display panel 100. The second scan driving circuit GDC2 may be disposed in the non-display area NDA on a second side (e.g., right side) of the display panel 100.

The first emission driving circuit EDC1 and the second emission driving circuit EDC2 may be electrically connected to emission control lines of the display area DA. The first emission driving circuit EDC1 may be disposed in the non-display area NDA on the first side (e.g., left side) of the display panel 100. The second emission driving circuit EDC2 may be disposed in the non-display area NDA on the second side (e.g., right side) of the display panel 100.

The first scan driving circuit GDC1 may be disposed between the display area DA and the first emission driving circuit EDC1. The first scan driving circuit GDC1 may be disposed closer to the display area DA than the first emission driving circuit EDC1. For example, the first emission driving circuit EDC1 may be disposed closer to an edge portion of the display panel 100 on the first side than the first scan driving circuit GDC1.

The second scan driving circuit GDC2 may be disposed between the display area DA and the second emission driving circuit EDC2. The second scan driving circuit GDC2 may be disposed closer to the display area DA than the second emission driving circuit EDC2. For example, the second emission driving circuit EDC2 may be disposed closer to an edge portion of the display panel 100 on the second side than the second scan driving circuit GDC2.

The dam area DMA may include at least one dam for preventing an encapsulating organic layer from overflowing to the display pads PD. The dam area DMA may surround the display area DA.

The dam area DMA may be disposed outside the first emission driving circuit EDC1 and outside the second emission driving circuit EDC2. The dam area DMA may be disposed closer to the edge portion of the display panel 100 on the first side than the first emission driving circuit EDC1. For example, the dam area DMA may be disposed closer to the edge portion of the display panel 100 on the second side than the second emission driving circuit EDC2.

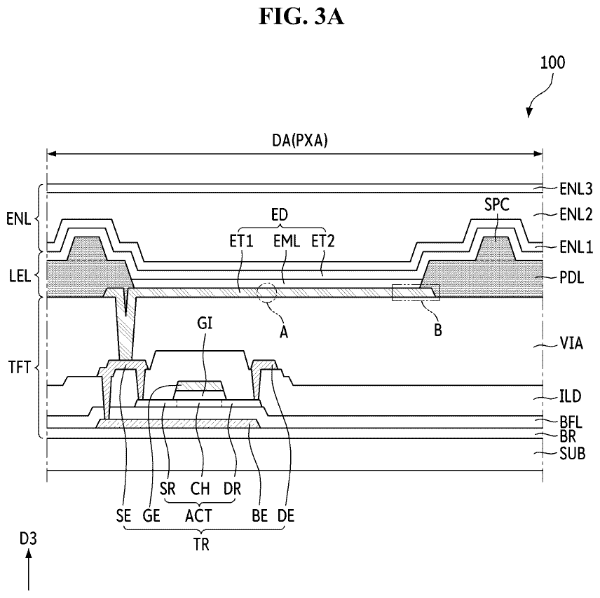

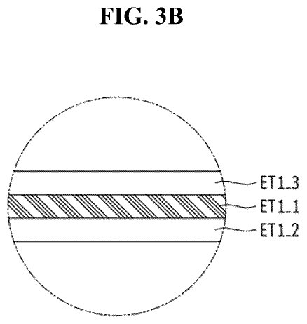

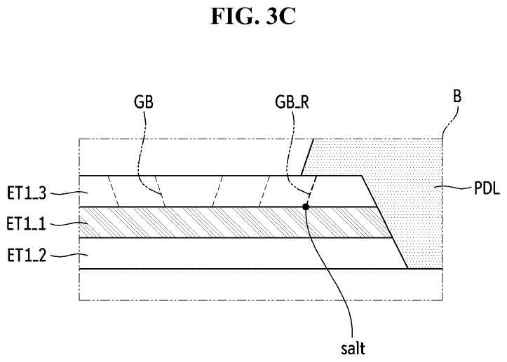

FIG. 3A is a schematic cross-sectional view of the display panel 100 according to the embodiment. For example, FIG. 3A illustrates a portion of the display area DA of the display panel 100. FIG. 3A illustrates, as an example of the display panel 100 to which embodiments are applied, a light emitting display panel including a light emitting element ED (e.g., an organic light emitting diode).

Referring to FIG. 3A, the display panel 100 may include a substrate SUB (or a base layer), a thin-film transistor layer TFT, a light emitting element layer LEL, and an encapsulation layer ENL. The thin-film transistor layer TFT, the light emitting element layer LEL, and the encapsulation layer ENL may be disposed on the substrate SUB to overlap each other. For example, in the display area DA, the thin-film transistor layer TFT, the light emitting element layer LEL, and the encapsulation layer ENL may be sequentially disposed on the substrate SUB along a third direction D3.

In an embodiment, the display panel 100 may further include additional elements disposed on and/or under the encapsulation layer ENL. For example, the display panel 100 may further include at least one of a sensor layer (e.g., a touch sensor layer), an optical layer (e.g., a color filter layer and/or a wavelength conversion layer), and a protective layer (e.g., a protective film, an insulating layer, an upper substrate, and/or a window). Each of the sensor layer, the optical layer, and/or the protective layer may be disposed on the encapsulation layer ENL or may be disposed between the light emitting element layer LEL and the encapsulation layer ENL.

The substrate SUB may be a base member for forming the display panel 100 and may be rigid or flexible. In an embodiment, the substrate SUB may be a substrate that includes an insulating material such as glass and has rigid characteristics and may not be bent. In another example, the substrate SUB may be a flexible substrate that includes polyimide or other insulating materials and may be bent, folded, rolled, etc. and may be or may not be bent.

The thin-film transistor layer TFT (e.g., a backplane circuit layer or a thin-film transistor layer) may be disposed on the substrate SUB. The thin-film transistor layer TFT may include circuit elements of pixels PX, including pixel transistors and capacitors C, and lines (e.g., signal lines and power lines). In an embodiment, the thin-film transistor layer TFT may further include circuit elements of at least one of the first scan driving circuit GDC1, the second scan driving circuit GDC2, the first emission driving circuit EDC1 and the second emission driving circuit EDC2, for example, may further include circuit transistors and/or capacitors.

FIG. 3A illustrates, as an example of circuit elements that are disposed in the thin-film transistor layer TFT, a transistor TR disposed in a pixel area PXA where one pixel PX is disposed and included in a pixel circuit of the pixel PX. The transistor TR may be a switching transistor or a driving transistor.

In an embodiment, the pixel transistors may be formed simultaneously using the same material and may have substantially the same or similar cross-sectional structure. For example, transistors TR of the pixels PX may be formed simultaneously using the same oxide semiconductor and may have substantially the same or similar cross-sectional structure. For example, active layers ACT of the transistors TR may be disposed at a same layer (e.g., on a buffer layer BFL) within the thin-film transistor layer TFT and may include the same oxide semiconductor.

The thin-film transistor layer TFT may include multiple conductive layers and at least one semiconductor layer disposed on the substrate SUB (or a barrier layer BR). For example, the thin-film transistor layer TFT may further include multiple insulating layers and/or insulating patterns disposed on the substrate SUB (or the barrier layer BR).

Patterns included in the conductive layers of the thin-film transistor layer TFT may include electrodes constituting circuit elements of the thin-film transistor layer TFT, conductive patterns and/or lines connected to the circuit elements, etc. The patterns included in each conductive layer of the thin-film transistor layer TFT (e.g., the electrodes, conductive patterns, and/or lines of each conductive layer) may include at least one conductive material. For example, the patterns included in each conductive layer of the thin-film transistor layer TFT may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg) and other metals, an alloy thereof, or other conductive materials. In an embodiment, patterns included in the same conductive layer may be formed simultaneously using the same conductive material.

Patterns included in the semiconductor layer of the thin-film transistor layer TFT may include the active layers ACT of transistors (e.g., pixel transistors and circuit transistors) disposed within the thin-film transistor layer TFT. In an embodiment, the active layers ACT of the pixel transistors and the circuit transistors may be formed simultaneously using the same semiconductor material (e.g., the same oxide semiconductor). Accordingly, the active layers ACT of the pixel transistors and the circuit transistors may be disposed at a same layer and may include the same semiconductor material.

The insulating layers and/or insulating patterns of the thin-film transistor layer TFT may include the barrier layer BR, the buffer layer BFL, a gate insulating layer GI, an interlayer insulating layer ILD, and a planarization layer VIA sequentially disposed on the substrate SUB along the third direction D3. Each of the insulating layers and/or insulating patterns of the thin-film transistor layer TFT may include an inorganic insulating material or an organic insulating material and may be composed of a single layer or multiple layers.

In an embodiment, at least one of the insulating layers of the thin-film transistor layer TFT may be disposed over the entire display area DA. For example, the barrier layer BR, the buffer layer BFL, the interlayer insulating layer ILD, and the planarization layer VIA may be disposed over the entire display area DA.

The structure of the thin-film transistor layer TFT will be described layer by layer. First, the barrier layer BR may be disposed on the substrate SUB. The barrier layer BR may include at least one inorganic insulating layer including an inorganic insulating material (e.g., silicon nitride (SiNₓ), silicon oxide (SiOₓ), silicon oxynitride (SiOₓN_{y}), titanium oxide (TiOₓ), aluminum oxide (AlₓO_{y}), or other inorganic insulating materials). The barrier layer BR may protect the pixels PX from moisture introduced through the substrate SUB which is vulnerable to moisture penetration. In another example, the barrier layer BR may also be omitted.

A first conductive layer (e.g., a lower conductive layer) including a bottom electrode BE (or a light blocking layer) of at least one transistor may be disposed on the barrier layer BR (or the substrate SUB). For example, the bottom electrode BE (or the light blocking layer) of a driving transistor DT may be disposed on the barrier layer BR. The bottom electrode BE may be disposed under an active layer ACT to overlap a channel region CH of the driving transistor DT. In an embodiment, the bottom electrode BE may also overlap at least a portion of each of a source region SR and a drain region DR of the transistor TR, but embodiments are not limited thereto. Each of the patterns of the first conductive layer including the bottom electrode BE may include at least one conductive material and may be composed of a single layer or multiple layers.

In an embodiment, the bottom electrode BE may be electrically connected to an electrode (e.g., a source electrode SE) of the transistor TR and may be utilized as an electrode for adjusting the characteristics of the transistor TR. For example, the bottom electrode BE may be electrically connected to the source electrode SE of the transistor TR. In case that the bottom electrode BE is electrically connected to the electrode of the transistor TR, it may be viewed as a component included in the transistor TR. The bottom electrode BE disposed under the active layer ACT of the transistor TR may block external light from being incident on the channel region CH of the transistor TR. In an embodiment, in case that the transistors of the thin-film transistor layer TFT do not include the bottom electrode BE or the light blocking layer, the first conductive layer may be omitted.

The buffer layer BFL may be disposed on the barrier layer BR and the bottom electrode BE. The buffer layer BFL may include at least one inorganic insulating layer including an inorganic insulating material (e.g., silicon nitride (SiNₓ), silicon oxide (SiOₓ), silicon oxynitride (SiOₓN_{y}), titanium oxide (TiOₓ), aluminum oxide (AlₓO_{y}), or other inorganic insulating materials).

The buffer layer BFL may include an insulating material suitable as a barrier material that prevents diffusion of oxygen, hydrogen, etc. The buffer layer BFL may include an insulating material that appropriately blocks oxygen, hydrogen, and/or moisture, in addition to a silicon nitride layer including silicon nitride (SiNₓ) and a silicon oxide layer including silicon oxide (SiOₓ).

Each of the pixel transistors may include an active layer ACT disposed on the buffer layer BFL and a gate electrode GE overlapping a portion of the active layer ACT. The gate insulating layer GI may be disposed between the active layer ACT and the gate electrode GE of each of the pixel transistors. In an embodiment, each of the pixel transistors may further include at least one of a drain electrode DE electrically connected to the drain region DR of the active layer ACT and a source electrode SE electrically connected to the source region SR of the active layer ACT. In another example, at least one pixel transistor may not include the drain electrode DE and the source electrode SE, and the drain region DR and the source region SR of the active layer ACT may function as a drain electrode and a source electrode.

The active layers ACT of the pixel transistors may be disposed on the buffer layer BFL. For example, a semiconductor layer including the active layers ACT may be disposed on the buffer layer BFL. The semiconductor layer may be covered with the gate insulating layer GI and the interlayer insulating layer ILD.

Each of the active layers ACT may include the channel region CH, the source region SR, and the drain region DR. The channel region CH may overlap the gate electrode GE in the third direction D3 in plan view and may be disposed between the source region SR and the drain region DR. The source region SR and the drain region DR may be disposed on sides (e.g., opposite sides) of the channel region CH and may be spaced apart from each other with the channel region CH between the source region SR and the drain region DR. The source region SR and the drain region DR (or a portion of each of the source region SR and the drain region DR) may not overlap the gate electrode GE in plan view. The carrier concentration (e.g., electron concentration) of the source region SR and the drain region DR may be higher than the carrier concentration of the channel region CH.

In an embodiment, the active layers ACT of the pixel transistors may include an oxide semiconductor. For example, the active layers ACT of the pixel transistors may include an oxide semiconductor including at least one of indium (In), gallium (Ga), zinc (Zn), tin (Sn) and hafnium (Hf) or other oxide semiconductors. For example, the active layers ACT of the pixel transistors may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO) and indium-tin-gallium-zinc oxide (ITGZO) or other oxide semiconductors.

In embodiments, the active layers ACT of some of the transistors disposed within the thin-film transistor layer TFT, including the pixel transistors, may be disposed on the buffer layer BFL.

In an embodiment, at least one transistor TR may be disposed in each pixel area PXA. Accordingly, multiple transistors TR may be disposed in the display area DA.

The gate insulating layer GI may be disposed on the active layers ACT of the pixel transistors. For example, the gate insulating layer GI may be disposed on a portion of each of the active layers ACT including the channel regions CH.

The gate insulating layer GI may include at least one inorganic insulating layer including an inorganic insulating material (e.g., silicon nitride (SiNₓ), silicon oxide (SiOₓ), silicon oxynitride (SiOₓN_{y}), titanium oxide (TiOₓ), aluminum oxide (AlₓO_{y}), or other inorganic insulating materials).

In an embodiment, in each transistor area where a transistor is disposed, the gate insulating layer GI may be etched to cover a portion of the active layer ACT included in the transistor and expose another portion of the active layer ACT. For example, in an area where a transistor TR is disposed, the gate insulating layer GI may cover the channel region CH of the active layer ACT included in the transistor TR and expose the source region SR and the drain region DR of the active layer ACT.

Since the gate insulating layer GI exposes the source regions SR and the drain regions DR, the conductivity of the source regions SR and the drain regions DR may be increased appropriately and/or readily during a process of manufacturing the display panel 100. For example, due to oxygen vacancies created in the source regions SR and the drain regions DR in a process of etching the gate insulating layer GI to expose at least a portion of each of the source regions SR and the drain regions DR, the carrier concentration of the source regions SR and the drain regions DR may increase in a subsequent process (e.g., a process of forming the interlayer insulating layer ILD) without performing a doping process.

However, embodiments are not limited thereto. For example, the gate insulating layer GI may also cover (e.g., entirely cover) the active layers ACT of some or all of the transistors included in the thin-film transistor layer TFT, except for contact holes for connecting each transistor to other circuit elements or lines.

A second conductive layer (e.g., a gate conductive layer) including the gate electrodes GE of the pixel transistors may be disposed on the gate insulating layer GI. For example, the gate electrode GE of a transistor TR may be disposed on the gate insulating layer GI covering the channel region CH of the transistor TR. Each of the patterns of the second conductive layer including the gate electrodes GE may include at least one conductive material and may be composed of a single layer or multiple layers.

The interlayer insulating layer ILD may be disposed on the buffer layer BFL, the semiconductor layer including the active layers ACT, the gate insulating layer GI, and the second conductive layer including the gate electrodes GE. For example, the interlayer insulating layer ILD may be disposed on the buffer layer BFL to cover the semiconductor layer, the gate insulating layer GI, and the patterns of the second conductive layer. The interlayer insulating layer ILD may include at least one inorganic insulating layer including an inorganic insulating material.

A third conductive layer (e.g., a source-drain conductive layer) including the source electrodes SE and the drain electrodes DE of the pixel transistors and/or conductive patterns electrically connected to at least some of the pixel transistors may be disposed on the interlayer insulating layer ILD. For example, the third conductive layer may include the source electrodes SE and the drain electrodes DE of the transistors TR. Each of the patterns of the third conductive layer may include at least one conductive material and may be composed of a single layer or multiple layers.

The source electrode SE and the drain electrode DE of each transistor TR may penetrate the interlayer insulating layer ILD and may be electrically connected to the source region SR and the drain region DR of the transistor TR, respectively. In an embodiment, the source electrode SE of each transistor TR may also penetrate the interlayer insulating layer ILD and the buffer layer BFL and may be electrically connected to the bottom electrode BE of the transistor TR.

The planarization layer VIA may be disposed on the pixel transistors. For example, the planarization layer VIA may be disposed on the interlayer insulating layer ILD and the third conductive layer. The planarization layer VIA may include at least one organic insulating layer including an organic insulating material (e.g., acryl resin, epoxy resin, phenolic resin, polyamide resin, polyimide resin, or other organic insulating materials). The planarization layer VIA may include an inorganic insulating layer or may not include an inorganic insulating layer. A surface (e.g., an upper surface) of the planarization layer VIA may be substantially flat.

The light emitting element layer LEL may be disposed on the thin-film transistor layer TFT. For example, the light emitting element layer LEL may be disposed on the planarization layer VIA and may be disposed at least in the display area DA.

The light emitting element layer LEL may include a light emitting element ED of each pixel PX. For example, the light emitting element layer LEL may include a pixel defining layer PDL (also referred to as a “bank”) that defines an emission area of each pixel PX and a light emitting element ED disposed in each emission area. In an embodiment, the light emitting element layer LEL may further include a spacer SPC disposed on a portion of the pixel defining layer PDL.

Each light emitting element ED may include a first electrode ET1 disposed in an emission area and a light emitting layer EML and a second electrode ET2 sequentially disposed on the first electrode ET1. The first electrode ET1 of each light emitting element ED may penetrate the planarization layer VIA and may be electrically connected to at least one pixel transistor (e.g., a transistor TR) included in a corresponding pixel PX.

The first electrode ET1 of each light emitting element ED may be a single-layer electrode or a multilayer electrode including at least one conductive material. In an embodiment, the display panel 100 may be a top emission display panel, and the first electrode ET1 may include a reflective electrode layer having high reflectivity. Since the first electrode ET1 is a main feature of the disclosure, it will be described in detail later.

The light emitting layer EML of each light emitting element ED may include a high-molecular material or a low-molecular material. Light emitted from the light emitting layer EML may contribute to image display.

Although FIG. 3A illustrates the display panel 100 in which the light emitting layer EML of a light emitting element ED is individually formed in each pixel area PXA, embodiments are not limited thereto. For example, the display panel 100 may also include light emitting elements having a tandem structure that includes the light emitting layer EML formed as a common layer over the entire display area DA.

The second electrode ET2 of each light emitting element ED may include a conductive material. In an embodiment, the second electrode ET2 may be a common layer formed over the entire display area DA to cover the light emitting layer EML and the pixel defining layer PDL. In an embodiment, the display panel 100 may be a top emission display panel, and the second electrode ET2 may include a transparent or translucent electrode layer.

In a top emission structure, the second electrode ET2 may be made of a transparent conductive material (TCO) that transmits light, such as indium tin oxide (ITO) or indium zinc oxide (IZO), or a semi-transmissive conductive material such as magnesium (Mg), silver (Ag) or an alloy of Mg and Ag. In case that the second electrode ET2 is made of a semi-transmissive conductive material, the light output efficiency of each light emitting element ED may be increased by a microcavity.

The positions of the first electrode ET1 and the second electrode ET2 may be reversed.

The pixel defining layer PDL may have an opening corresponding to (or overlapping) each emission area and may surround each emission area. For example, the pixel defining layer PDL may be formed to cover an edge portion of the first electrode ET1 of each light emitting element ED and may include an opening exposing the other portion of the first electrode ET1. An area where the exposed first electrode ET1 and the light emitting layer EML overlap may be the emission area of each pixel PX. In an embodiment, the pixel defining layer PDL may be made of an organic material. The pixel defining layer PDL may include a light blocking material. The pixel defining layer PDL may include a base resin and a colorant. The base resin may include at least one of cardo resin, epoxy resin, acrylate resin, siloxane resin, and polyimide. The colorant may be selected from a carbon pigment, a metal oxide pigment, and an organic pigment. For example, the carbon pigment may be selected from carbon black, carbon nanotubes, titanium black, and vertically aligned nanotube arrays (VANTA) black, but embodiments are not limited thereto. For example, the metal oxide pigment may be titanium black (TiNₓO_{y}), Cu—Mn—Fe black pigment, but embodiments are not limited thereto. For example, the organic pigment may be selected from lactam black, perylene black, and aniline black, but embodiments are not limited thereto. For another example, the colorant may be a mixture of two or more pigments or dyes having different colors, but embodiments are not limited thereto.

The pixel defining layer PDL may include a halogen element. The halogen element may be added during a process of manufacturing the pixel defining layer PDL and may not be removed during purification. In another example, a material including the halogen element may be used as the pixel defining layer PDL.

The halogen element may include at least one of Cl, Br, and I.

The spacer SPC may be disposed on a portion of the pixel defining layer PDL. The spacer SPC may include at least one organic insulating layer including an organic insulating material. The spacer SPC may include the same material as the pixel defining layer PDL or a different material from the pixel defining layer PDL. The pixel defining layer PDL and the spacer SPC may be sequentially formed through each mask process or may be simultaneously and/or integrally formed using a halftone mask.

The encapsulation layer ENL may be disposed on the light emitting element layer LEL. The encapsulation layer ENL may cover the light emitting element layer LEL in the display area DA and may extend to the non-display area NDA to contact the thin-film transistor layer TFT. The encapsulation layer ENL may block the penetration of oxygen or moisture into the light emitting element layer LEL and mitigate electrical and/or physical impacts on the thin-film transistor layer TFT and the light emitting element layer LEL.

In an embodiment, the encapsulation layer ENL may include a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

The first electrode ET1, which is a main feature of the display device 10 according to the embodiment of the disclosure, will now be described.

FIG. 3B is an enlarged schematic cross-sectional view of area A of the display panel 100 according to the embodiment.

Referring to FIG. 3B, the first electrode ET1 may include a second conductive layer ET1_2, a first conductive layer ET1_1 disposed on the second conductive layer ET1_2, and a third conductive layer ET1_3 disposed on the first conductive layer ET1_1.

The second conductive layer ET1_2 and the third conductive layer ET1_3 may include a conductive oxide.

The conductive oxide may include at least one of indium-tin oxide (ITO), zinc oxide (ZnO), zinc-tin oxide (ZTO), indium-zinc oxide (IZO), indium-gallium oxide (IGO), indium-gallium-zinc oxide (IGZO), indium-gallium-tin oxide (IGTO), indium-tin-zinc oxide (ITZO), aluminum-doped zinc oxide (AZO), gallium-doped zinc oxide (GZO), gallium-tin oxide (GTO), and fluorine-doped tin oxide (FTO).

The third conductive layer ET1_3 may be designed to improve a potential barrier between the first conductive layer ET1_1 and the light emitting layer EML. For example, a work function of indium-tin oxide (ITO) may be about 5.2 eV, and a work function of the light emitting layer EML may be about 5.1 eV. Since a difference in work function between the indium tin oxide (ITO) and the light emitting layer EML is small, electronic transfer may readily occur.

The first conductive layer ET1_1 may include silver (Ag), palladium (Pd), and copper (Cu). For example, the first conductive layer ET1_1 may include about 97 wt % to about 99 wt % of silver (Ag), about 0.1 wt % to about 2.9 wt % of palladium (Pd), and about 0.1 wt % to about 2.9 wt % of copper (Cu). For example, the first conductive layer ET1_1 may be an alloy composed of about 97 wt % to about 99 wt % of silver (Ag), about 0.1 wt % to about 2.9 wt % of palladium (Pd), and about 0.1 wt % to about 2.9 wt % of copper (Cu). The sum of the content of silver (Ag), the content of palladium (Pd), and the content of copper (Cu) in the first conductive layer ET1_1 may be about 100 wt % or less.

Since the display device 10 according to the embodiment of the disclosure includes the first electrode ET1 which includes the first conductive layer including about 97 wt % to about 99 wt % of silver (Ag), about 0.1 wt % to about 2.9 wt % of palladium (Pd), and about 0.1 wt % to about 2.9 wt % of copper (Cu), it is possible to achieve high reflectance while preventing the creation of voids.

FIG. 3C is an enlarged schematic cross-sectional view of area B of the display panel 100 according to the embodiment.

Referring to FIG. 3C, as an amorphous material of the third conductive layer ET1_3 changes into a crystalline material during a high-temperature post-processing process, a grain boundary GB may be generated. A grain boundary GB_R generated in the third conductive layer ET1_3 in an area in contact with the pixel defining layer PDL may serve (or function) as a passage through which halogen ions included in the pixel defining layer PDL and silver (Ag) ions of the first conductive layer ET1_1 can move. The halogen ions included in the pixel defining layer PDL and the silver (Ag) ions of the first conductive layer ET1_1 may meet through the grain boundary GB_R and may combine to generate salt (AgCl, AgBr, AgI, AgS, etc.). The generated salt may be removed by a cleaning process. However, voids may be formed on portions of surfaces of the first conductive layer ET1_1 and the third conductive layer ET1_3 from which the salt has been removed during the cleaning process. The voids may cause a step on a surface of the first electrode ET1. Therefore, a current flowing from the first electrode ET1 to the second electrode ET2 through the light emitting layer EML may not be uniform within the first electrode ET1. For example, due to the surface step of the first electrode ET1, a largest amount of current may flow where the light emitting layer EML is thin, or a short circuit may even occur between the first electrode ET1 and the second electrode ET2, thereby resulting in a dark spot.

For example, the third conductive layer ET1_3 may be removed together with the salt during the cleaning process. In case that the light emitting layer EML is formed on the first conductive layer ET1_1 from which the third conductive layer ET1_3 has been removed, electron transfer may not occur readily due to the difference in work function between the first conductive layer ET1_1 and the light emitting layer EML.

In case that the first electrode ET1 is made of an APC alloy with reduced silver (Ag) content, the generation of salt due to the combination of silver (Ag) and halogen elements may be reduced compared to when the first electrode ET1 is made of only silver (Ag). Therefore, defects such as salt, voids, and dark spots which are generated in case that the first electrode ET1 is made of silver (Ag) may be prevented or minimized.

In case that the first conductive layer ET1_1 includes less than about 97 wt % of silver (Ag), light absorbance of the display device 10 including the first conductive layer ET1_1 may increase, thereby lowering light efficiency. In case that the first conductive layer includes more than about 99 wt % of silver (Ag), a defect may occur in the display panel 100 including the first conductive layer ET1_1.

A transistor TR including a semiconductor layer made of an oxide semiconductor may be sensitive to light from the outside, and thus the characteristics of a device may change according to light. In order to maintain the reliability of the device, the light from the outside may be blocked. For example, the pixel defining layer PDL may include a light blocking material. The pixel defining layer PDL including the light blocking material may be formed on the transistor TR to effectively block light that is applied to the transistor TR and improve the reliability of the device.

The pixel defining layer PDL may include at least one halogen element among Cl, Br, and I. The content of at least one halogen element in the pixel defining layer PDL may be in a range of about 1 wt % to about 30 wt %.

The light blocking material included in the pixel defining layer PDL may include halogen.

The halogen element may include a halogen element that remains without being completely purified during a g-synthesis process in case that a compound for forming the pixel defining layer PDL is synthesized. For example, in case that cardo resin is synthesized, a dihydroxy cardo compound and epichlorohydrin may be reacted to obtain cardo resin. For example, a large amount of chlorine may be generated as a byproduct of the synthesis, and the chlorine may remain even after purification.

In order to improve the reliability of a transistor TR including a semiconductor layer made of an oxide semiconductor, the pixel defining layer PDL may include a light blocking material that blocks light. The light blocking material of the pixel defining layer PDL may include a large amount of halogen elements.

For example, an appropriate amount of palladium (Pd) and copper (Cu) included in addition to silver (Ag) may increase the adhesion between the silver (Ag), the palladium (Pd), and the copper (Cu), thereby suppressing an ionization phenomenon of the silver (Ag). Since the ionization phenomenon of the silver (Ag) is suppressed, the generation of salt due to the reaction between halogen ions included in the pixel defining layer PDL and the silver (Ag) may be prevented or minimized, which, in turn, suppresses defects such as voids and dark spots.

Therefore, the first electrode ET1 including the first conductive layer which includes about 97 wt % to about 99 wt % of silver (Ag), about 0.1 wt % to about 2.9 wt % of palladium (Pd), and about 0.1 wt % to about 2.9 wt % of copper (Cu) is improved in heat resistance and chemical resistance while the reflection efficiency of the display device 10 is maintained.

A method of manufacturing a display device 10 relates to a method of manufacturing the display device 10 described above. The method of manufacturing the display device 10 will be described, focusing on differences from the display device 10, and redundant descriptions will be omitted for descriptive convenience.

A method of manufacturing a display device according to an embodiment of the disclosure may include forming a transistor TR, which includes a semiconductor layer, on a substrate SUB; forming a first electrode ET1 on the transistor TR; forming a pixel defining layer PDL which includes an opening exposing at least a portion of the first electrode ET1; forming a light emitting layer EML on the first electrode ET1 in the opening; and forming a second electrode ET2 on the light emitting layer EML and the pixel defining layer PDL. The forming of the first electrode ET1 may include forming a first conductive layer under an oxygen (O₂) concentration of about 3% or less, and the first conductive layer may include silver (Ag), palladium (Pd), and copper (Cu).

The forming of the first electrode ET1 may include forming a second conductive layer ET1_2 including a conductive oxide; forming a first conductive layer ET1_1 on the second conductive layer ET1_2; and forming a third conductive layer ET1_3 including a conductive oxide on the first conductive layer ET1_1.

The first conductive layer ET1_1 including about 97 wt % to about 99 wt % of silver (Ag), about 0.1 wt % to about 2.9 wt % of palladium (Pd), and about 0.1 wt % to about 2.9 wt % of copper (Cu) may be formed under an oxygen (O₂) concentration of about 3% or less.

Since the first conductive layer ET1_1 is formed under an oxygen concentration condition of about 3% or less, reflection efficiency may be maintained similarly to when silver (Ag) is used as an electrode.

For example, the display device 10 manufactured using the manufacturing method of the current embodiment may maintain low surface resistance even in high temperature and high humidity conditions.

Hereinafter, the disclosure will be described in more detail through the following examples. However, the following examples are intended for the purpose of explanation only and are not intended to limit the scope of the disclosure.

### 1. Manufacture of Display Device

### 1) Example 1

A display panel using indium-gallium-zinc oxide (IGZO) as a semiconductor layer and a cardo compound of reaction formula 1 below as a pixel defining layer was prepared. ITO was prepared as a first electrode of the display panel. A conductive layer was formed on the ITO under an oxygen concentration condition of 0% by using an alloy of 98% silver (Ag), 1% palladium (Pd), and 1% copper (Cu) as a target. ITO was formed on the conductive layer. A display panel (ITO/APC (O₂: 0%)/ITO) using an ITO/98% Ag, 1% Pd, 1% Cu/ITO structure as the first electrode was manufactured.

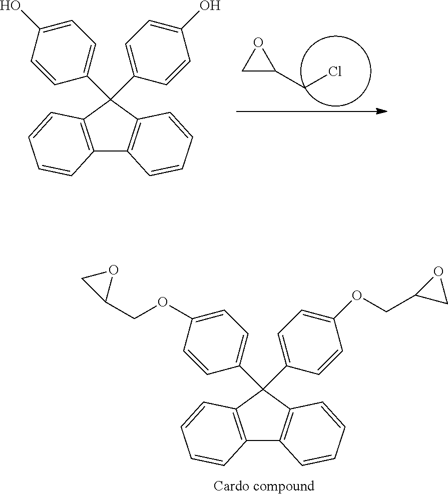 [SMILES: Oc1ccc(C2(c3ccc(O)cc3)c3ccccc3-c3ccccc32)cc1 ; ClCC1CO1 ; c1ccc2c(c1)-c1ccccc1C2(c1ccc(OCC2CO2)cc1)c1ccc(OCC2CO2)cc1]

### 2) Example 2

A display panel (ITO/APC (O₂: 3.0%)/ITO) identical to Example 1 was manufactured, except that a conductive layer was formed under an oxygen concentration of 3%.

### 3) Comparative Example 1

A display panel identical to Example 1 was manufactured, except that ITO/Ag/ITO was used as a first electrode.

### 4) Comparative Example 2

A display panel identical to Example 1 was manufactured, except that ITO/99.1% Ag, 0.1% Pd, 0.8% Cu/ITO was used as a first electrode.

### 5) Comparative Example 3

A display panel identical to Example 1 was manufactured, except that ITO/96.9% Ag, 1.5% Pd, 1.6% Cu/ITO was used as a first electrode.

### 6) Comparative Example 4

A display panel (ITO/APC (O₂: 5.0%)/ITO) identical to Example 1 was manufactured, except that a conductive layer was formed under an oxygen concentration of 5%.

### 7) Comparative Example 5

A display panel (ITO/APC (O₂: 10.0%)/ITO) identical to Example 1 was manufactured, except that a conductive layer was formed under an oxygen concentration of 10%.

### 8) Comparative Example 6

A display panel (ITO/APC (O₂: 15.0%)/ITO) identical to Example 1 was manufactured, except that a conductive layer was formed under an oxygen concentration of 15%.

### Evaluation

### 1. Heat Resistance

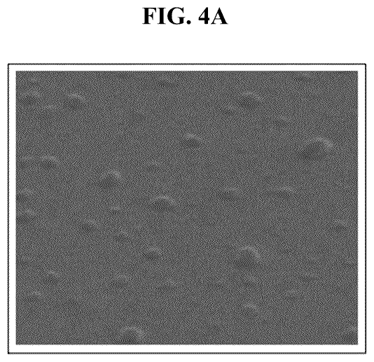

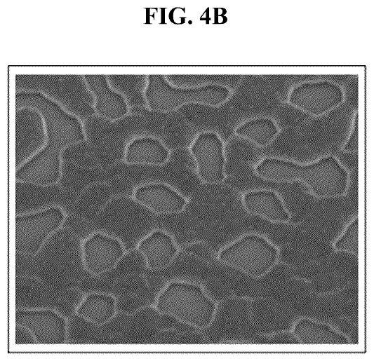

FIGS. 4A and 4B are respectively scanning electron microscope (SEM) images of surfaces of Example 1 and Comparative Example 1 measured after heat treatment at a temperature of 450° C. for one hour.

According to the results shown in FIG. 4B, it may be seen that the overall surface of Comparative Example 1 is uneven due to a lot of large pinholes formed after high-temperature treatment. On the other hand, it may be seen that Example 1 of FIG. 4A has an even surface compared to Comparative Example 1 even after heat treatment. This means that the heat resistance of the electrode according to an embodiment is higher than that of silver (Ag).

### 2. Light Efficiency

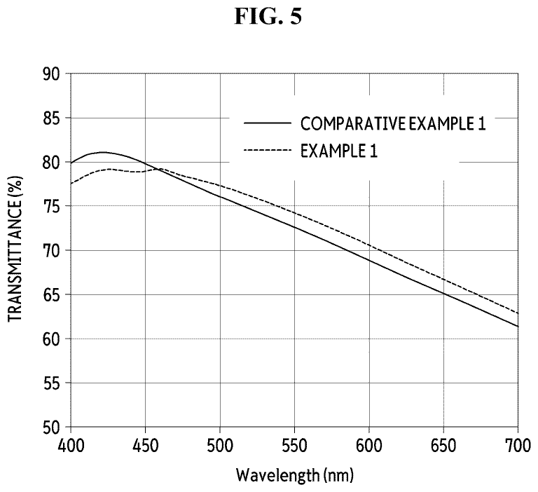

The light efficiency characteristics of the display panels manufactured as Example 1 and Comparative Example 1 with respect to wavelength region were measured, and the results are shown in FIGS. 5, 6, and 7 and Table 1.

FIG. 5 is a schematic graph illustrating the transmittance of the display panels of Example 1 and Comparative Example 1 with respect to wavelength region.

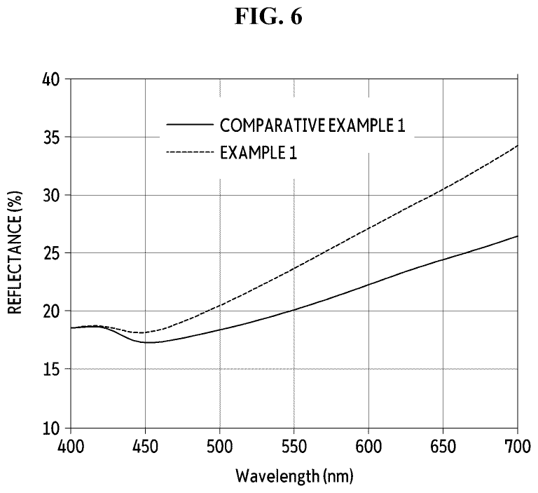

FIG. 6 is a schematic graph illustrating the reflectance of the display panels of Example 1 and Comparative Example 1 with respect to wavelength region.

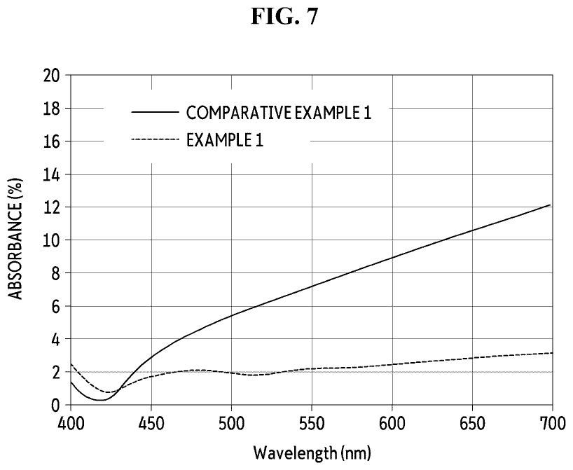

FIG. 7 is a schematic graph illustrating the absorbance of the display panels of Example 1 and Comparative Example 1 with respect to wavelength region.

Table 1 below shows the reflectance, absorbance, surface resistance and thermo-electric generator (TEG) efficiency of the display panels of Example 1 and Comparative Example 1.

TABLE 1

| | SCI | | Transmittance | | Absorbance | | | | | |
|---|---|---|---|---|---|---|---|---|---|---|
| | reflectance (%) | | (%) | | (%) | | | | | |
| | Avg | | Avg | | Avg | | Sheet | TEG efficiency | | |
| | (380~ | @550 | (380~ | @550 | (380~ | @550 | resistance | (cd/A/(y)) | | |
| | 780 nm) | nm | 780 nm) | nm | 780 nm) | nm | (Ω/□) | R | G | B |
| Example 1 | 27.0 | 24.1 | 70.7 | 73.3 | 2.3 | 2.6 | 11.4 | 54.5 | 146.2 | 135.4 |
| Comparative | 22.1 | 20.2 | 69.5 | 71.9 | 8.4 | 7.9 | 17.9 | 51.8 | 142.7 | 136.2 |
| example 1 | | | | | | | | | | |

According to the results shown in FIGS. 5, 6, and 7 and Table 1, Example 1 was measured to have higher reflectance and transmittance and lower absorbance and sheet resistance than Comparative Example 1. This means that Example 1 has better light efficiency than Comparative Example 1. It may also be seen that the TEG efficiency of Example 1 is higher than or similar to that of Comparative Example 1.

A conventional APC alloy (i.e., alloy of palladium, copper, and silver) has advantages such as high heat resistance and corrosion resistance compared to silver (Ag), but has the problem of lower light efficiency than silver (Ag). However, by adjusting the composition ratio of silver (Ag), palladium (Pd), and copper (Cu) as in the disclosure, it is possible to obtain an advantage of improving the light efficiency in addition to the advantages such as heat resistance and corrosion resistance.

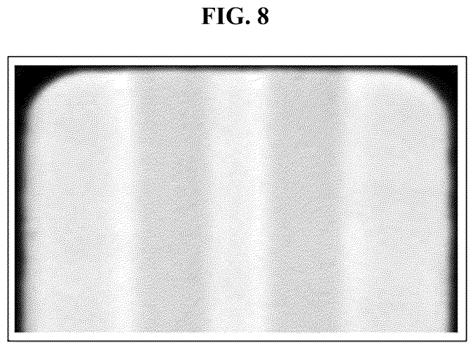

Surface images were obtained to measure the number of defects of the display panels manufactured as Example 1 and Comparative Examples 1 through 3, and the results are shown as FIGS. 8, 9, 10, and 11.

FIG. 8 is a surface image of the display panel manufactured according to Example 1.

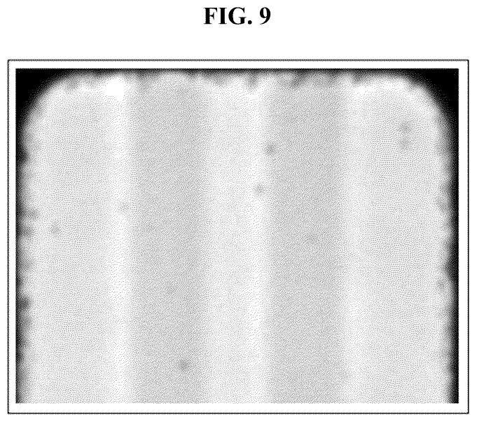

FIG. 9 is a surface image of the display panel manufactured according to Comparative Example 1.

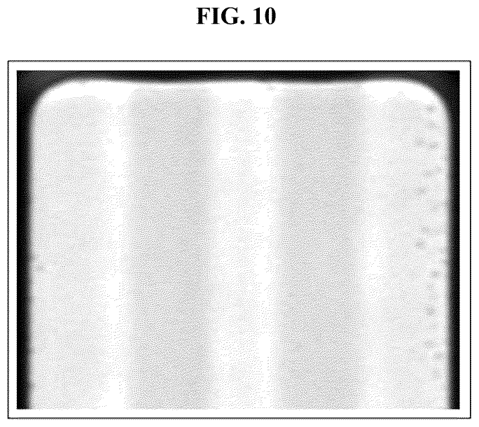

FIG. 10 is a surface image of the display panel manufactured according to Comparative Example 2.

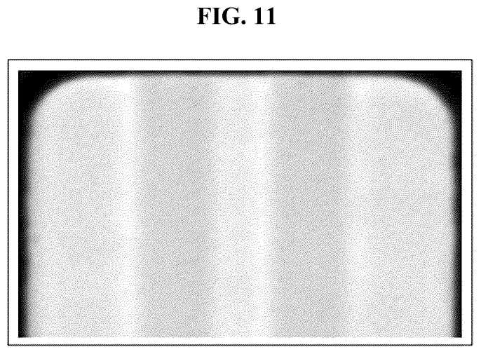

FIG. 11 is a surface image of the display panel manufactured according to Comparative Example 3.

36 points were randomly measured to measure the number of defects in the surface images of FIGS. 8, 9, 10, and 11. The number of defects of Example 1 shown in FIG. 8 was 1 out of 36 points, the number of defects of Comparative Example 1 shown in FIG. 9 was 16 out of 36 points, the number of defects of Comparative Example 2 shown in FIG. 10 was 8 out of 36 points, and the number of defects of Comparative Example 3 shown in FIG. 11 was 1 out of 36 points.

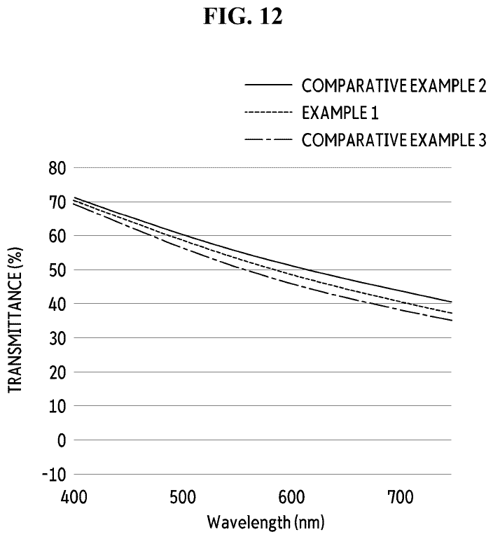

The light efficiency characteristics of the display panels manufactured as Example 1, Comparative Examples 2 and 3 with respect to wavelength region were measured, and the results are shown as FIGS. 12, 13, and 14.

FIG. 12 is a schematic graph illustrating the transmittance of the display panels of Example 1 and Comparative Examples 2 and 3 with respect to wavelength region.

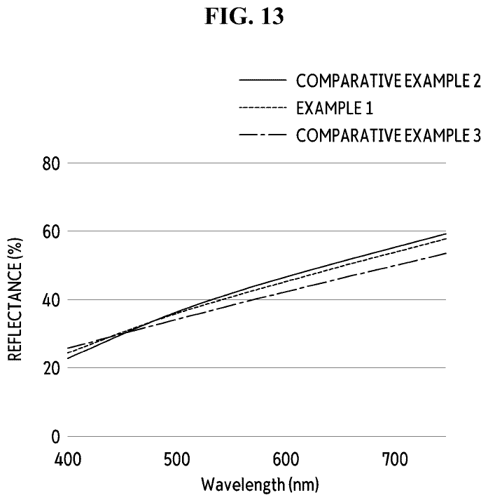

FIG. 13 is a schematic graph illustrating the reflectance of the display panels of Example 1 and Comparative Examples 2 and 3 with respect to wavelength region.

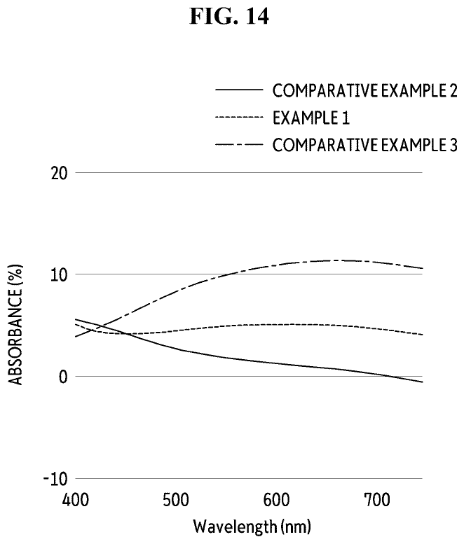

FIG. 14 is a schematic graph illustrating the absorbance of the display panels of Example 1 and Comparative Examples 2 and 3 with respect to wavelength region.

According to the results shown in FIG. 12, it may be seen that transmittance increases as the silver content increases.

According to the results shown in FIG. 13, it may be seen that reflectance increases as the silver content increases.

According to the results shown in FIG. 14, it may be seen that absorbance increases as the silver content decreases.

As is apparent from FIGS. 12, 13, and 14, the light efficiency of Comparative Example 2 is the highest. However, according to the results shown in FIG. 10, Comparative Example 2 has a disadvantage of low reliability due to a large number of defects.

According to the results shown in FIG. 11, Comparative Example 3 has almost no defects. However, the light efficiency of Comparative Example 3 is the lowest as shown in FIGS. 12, 13, and 14. Since Comparative Example 3 has low light efficiency due to its high absorbance, there are limitations in using Comparative Example 3 as a display device.

For example, a display panel in which silver (Ag), palladium (Pd), and copper (Cu) are combined in an appropriate composition ratio and used as an electrode according to an embodiment of the disclosure exhibits similar or better light efficiency than when silver (Ag) is used as an electrode, while defects such as voids are prevented or minimized. However, silver (Ag) content higher than 99% may improve the light efficiency of the display panel but causes defects such as voids. For example, silver (Ag) content lower than 97% may improve defects such as voids, but may reduce light efficiency. This suggests that a deviation from the appropriate composition ratio of silver (Ag), palladium (Pd), and copper (Cu) may cause defects such as voids or reduce light efficiency.

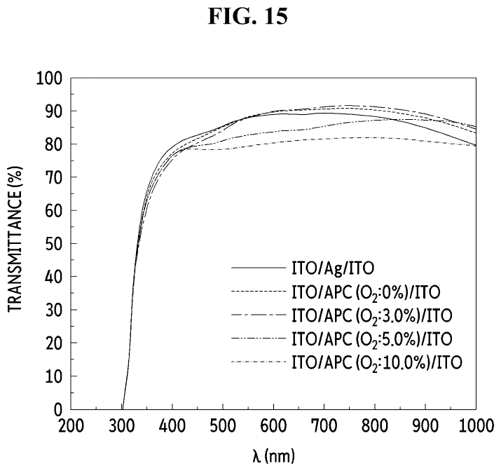

The light efficiency characteristics of the display panels manufactured as Examples 1 and 2 and Comparative Examples 1, 4 and 5 with respect to wavelength region were measured, and the results are shown in FIGS. 15, 16, and 17.

FIG. 15 is a schematic graph illustrating the transmittance of the display panels of Examples 1 and 2 and Comparative Examples 1, 4 and 5 with respect to wavelength region.

According to the results shown in FIG. 15, it may be seen that the transmittance of Examples 1 and 2 and Comparative Example 1 is consistently high in a visible light region, while the transmittance of Comparative Examples 4 and 5 is relatively low. This means that transmittance is reduced in case that an electrode is formed at a high oxygen concentration.

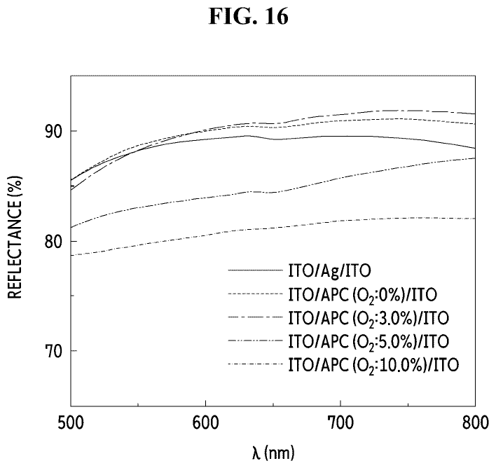

FIG. 16 is a schematic graph illustrating the reflectance of the display panels of Examples 1 and 2 and Comparative Examples 1, 4 and 5 with respect to wavelength region.

According to the results shown in FIG. 16, the reflectance of Examples 1 and 2 and Comparative Example 1 is consistently high in the visible light region, while the reflectance of Comparative Examples 4 and 5 is relatively low. This means that reflectance is reduced in case that an electrode is formed at a high oxygen concentration.

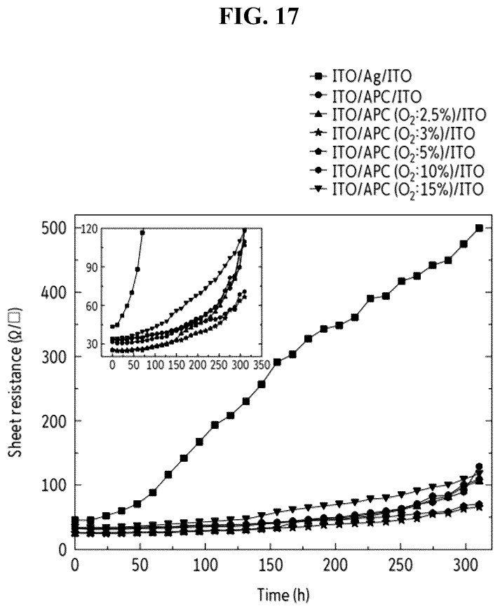

FIG. 17 is a schematic graph illustrating the sheet resistance of the display panels of Examples 1 and 2 and Comparative Examples 1, 4 and 5 over time.

FIG. 17 is a schematic graph illustrating the sheet resistance of the display panels over time in a high-temperature and high-humidity environment of 300° C. and 90%.

According to the results shown in FIG. 17, it may be seen that the sheet resistance of Comparative Example 1 increases rapidly over time. This is because silver (Ag) has weak heat resistance and corrosion resistance. On the other hand, in case that an alloy of 98% silver (Ag), 1% palladium (Pd), and 1% copper (Cu) is used, it may be seen that the surface resistance is maintained low even in a high-temperature and high-humidity environment. This means that the alloy of 98% silver (Ag), 1% palladium (Pd), and 1% copper (Cu) has excellent heat resistance and corrosion resistance. However, in the case of a display panel in which an electrode is formed under an oxygen concentration condition of 15% as in Comparative Example 6, it may be seen that the surface resistance increases over time in a high-temperature and high-humidity environment.

For example, a display panel in which silver (Ag), palladium (Pd), and copper (Cu) are combined in an appropriate composition ratio and formed as an electrode under an oxygen concentration of 3% or less according to an embodiment of the disclosure has excellent heat resistance and corrosion resistance and excellent light efficiency.

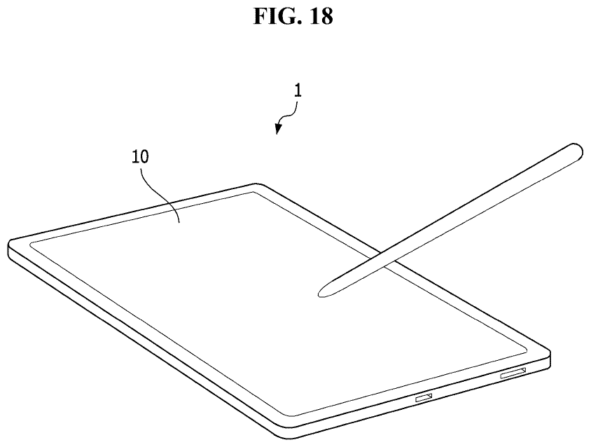

FIG. 18 is a schematic perspective view of an electronic device to which a display device 10 according to an embodiment is applied.

Referring to FIG. 18, a tablet 1 to which the display device 10 according to the embodiment is applied is illustrated as an example of the electronic device. However, the display device 10 according to the embodiment may also be applied to other electronic devices in addition to the tablet 1. For example, the display device 10 according to the embodiment may be applicable to an electronic device that displays a moving image or a still image. For example, the display device 10 according to the embodiment is applicable to portable electronic devices such as mobile phones, smart phones, smart watches, watch phones, mobile communication terminals, electronic notebooks, electronic books, PMPs, navigation devices, and UMPCs. In another example, the display device 10 according to the embodiment may be used as a display screen of various electronic devices such as a television, a notebook computer, a monitor, a billboard, and an IOT device.

In a display device according to embodiments, a conductive layer having an adjusted content composition ratio of silver, palladium and copper is applied to an electrode to improve an ionization phenomenon of silver (Ag), thereby suppressing reaction with a halogen element included in a pixel defining layer PDL. Therefore, the generation of salt due to the reaction with silver (Ag) may be prevented, and defects such as voids and dark spots may be suppressed.

The display device according to one embodiment of the present disclosure can be applied to various electronic devices. The electronic device according to the one embodiment of the present disclosure includes the display device described above, and may further include modules or devices having additional functions in addition to the display device.

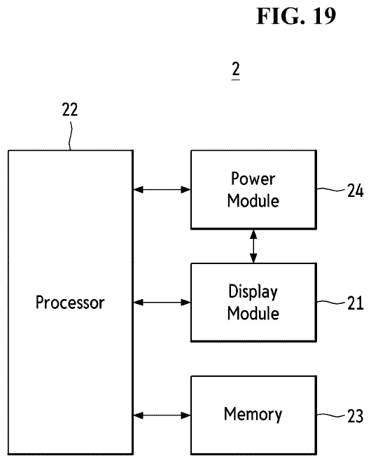

FIG. 19 is a block diagram of an electronic device according to one embodiment of the present disclosure.

Referring to FIG. 19, the electronic device 2 according to one embodiment of the present disclosure may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), and a controller.

The memory 23 may store data information necessary for the operation of the processor 22 or the display module 21. When the processor 22 executes an application stored in the memory 23, an image data signal and/or an input control signal is transmitted to the display module 21, and the display module 21 can process the received signal and output image information through a display screen.

The power module 24 may include a power supply module such as, for example a power adapter or a battery, and a power conversion module that converts the power supplied by the power supply module to generate power necessary for the operation of the electronic device 2.

At least one of the components of the electronic device 2 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 21, and the processor 22, the memory 23, and the power module 24 may be provided in the form of other devices within the electronic device 2 other than the display device 10.

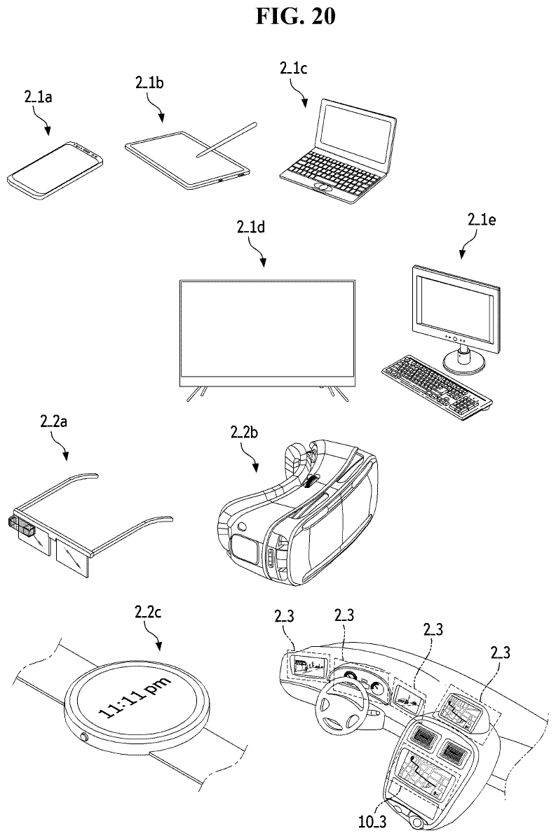

FIG. 20 is a schematic diagram of an electronic device according to various embodiments of the present disclosure.

Referring to FIG. 20, various electronic devices to which display devices 10 according to embodiments of the present disclosure are applied may include not only image display electronic devices such as a smart phone 2_1a, a tablet PC (personal computer) 2_1b, a laptop 2_1c, a TV 2_1d, and a desk monitor 2_1e, but also wearable electronic devices including display modules such as, for example smart glasses 2_2a, a head mounted display 2_2b, and a smart watch 2_2c, and vehicle electronic devices 2_3 including display modules such as a CID (Center Information Display) and a room mirror display arranged on a dashboard, center fascia, and dashboard of an automobile.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a substrate;
a first electrode disposed on the substrate;
a pixel defining layer comprising an opening which exposes at least a portion of the first electrode;
a light emitting layer disposed on the first electrode in the opening; and
a second electrode disposed on the light emitting layer and the pixel defining layer, wherein
the first electrode comprises a first conductive layer comprising silver (Ag), palladium (Pd) and copper (Cu), and
in the first conductive layer, content of the silver (Ag) is in a range of about 97 wt % to about 99 wt %, content of the palladium (Pd) is in a range of about 0.1 wt % to about 2.9 wt %, and content of the copper (Cu) is in a range of about 0.1 wt % to about 2.9 wt %.

2. The display device of claim 1, wherein the first electrode further comprises:
a second conductive layer disposed under the first conductive layer and comprising a conductive oxide; and
a third conductive layer disposed on the first conductive layer and comprising a conductive oxide.

3. The display device of claim 2, wherein the conductive oxide comprises at least one of indium-tin oxide (ITO), zinc oxide (ZnO), zinc-tin oxide (ZTO), indium-zinc oxide (IZO), indium-gallium oxide (IGO), indium-gallium-zinc oxide (IGZO), indium-gallium-tin oxide (IGTO), indium-tin-zinc oxide (ITZO), aluminum-doped zinc oxide (AZO), gallium-doped zinc oxide (GZO), gallium-tin oxide (GTO), and fluorine-doped tin oxide (FTO).

4. The display device of claim 1, wherein the pixel defining layer comprises at least one halogen element among Cl, Br, and I.

5. The display device of claim 4, wherein content of the at least one halogen element in the pixel defining layer is in a range of about 1 wt % to about 30 wt %.

6. The display device of claim 1, wherein the pixel defining layer comprises a light blocking material.

7. The display device of claim 1, further comprising:
a transistor which comprises a semiconductor layer disposed between the substrate and the first electrode and electrically connected to the first electrode,
wherein the semiconductor layer comprises an oxide semiconductor comprising at least one of indium (In), gallium (Ga), zinc (Zn), tin (Sn), and hafnium (Hf).

8. The display device of claim 7, wherein the semiconductor layer comprises at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO).

9. A method of manufacturing a display device, the method comprising:
forming a transistor, which comprises a semiconductor layer, on a substrate;
forming a first electrode on the transistor;
forming a pixel defining layer which comprises an opening exposing at least a portion of the first electrode;
forming a light emitting layer on the first electrode in the opening; and
forming a second electrode on the light emitting layer and the pixel defining layer, wherein
the forming of the first electrode comprises forming a first conductive layer under an oxygen (O₂) concentration of about 3% or less, and
the first conductive layer comprises silver (Ag), palladium (Pd) and copper (Cu).

10. The method of claim 9, wherein the first conductive layer comprises about 97 wt % to about 99 wt % of silver (Ag), about 0.1 wt % to about 2.9 wt % of palladium (Pd), and about 0.1 wt % to about 2.9 wt % of copper (Cu).

11. The method of claim 9, wherein
the forming of the first electrode comprises:
forming a second conductive layer comprising a conductive oxide before the forming of the first conductive layer, and
forming a third conductive layer comprising the conductive oxide on the first conductive layer, and
the first conductive layer is disposed on the second conductive layer.

12. The method of claim 11, wherein the conductive oxide comprises at least one of indium-tin oxide (ITO), zinc oxide (ZnO), zinc-tin oxide (ZTO), indium-zinc oxide (IZO), indium-gallium oxide (IGO), indium-gallium-zinc oxide (IGZO), indium-gallium-tin oxide (IGTO), indium-tin-zinc oxide (ITZO), aluminum-doped zinc oxide (AZO), gallium-doped zinc oxide (GZO), gallium-tin oxide (GTO), and fluorine-doped tin oxide (FTO).

13. The method of claim 9, wherein the pixel defining layer comprises at least one halogen element among Cl, Br, and I.

14. The method of claim 13, wherein content of the at least one halogen element in the pixel defining layer is in a range of about 1 wt % to about 30 wt %.

15. The method of claim 9, wherein the pixel defining layer comprises a light blocking material.

16. The method of claim 9, wherein the semiconductor layer comprises at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO), and indium-tin-gallium-zinc oxide (ITGZO).

17. An electronic device comprising:
a display device that provides an image; and
a processor that transmits an image data signal to the display device, wherein the display device comprising:
a substrate;
a first electrode disposed on the substrate;
a pixel defining layer comprising an opening which exposes at least a portion of the first electrode;
a light emitting layer disposed on the first electrode in the opening; and
a second electrode disposed on the light emitting layer and the pixel defining layer,
the first electrode comprises a first conductive layer comprising silver (Ag), palladium (Pd) and copper (Cu), and
in the first conductive layer, content of the silver (Ag) is in a range of about 97 wt % to about 99 wt %, content of the palladium (Pd) is in a range of about 0.1 wt % to about 2.9 wt %, and content of the copper (Cu) is in a range of about 0.1 wt % to about 2.9 wt %.
